(19) United States
(12) Patent Application Publication
(10) Pub. No.: US 2026/0223383 A1
(43) Pub. Date: Jul. 30, 2026

(54) HIGH VOLTAGE DIODE WITH TERMINATION STRUCTURE AND METHOD OF ITS FABRICATION

(71) Applicant: Tower Semiconductor Ltd., Migdal Haemek (IL)

(72) Inventors: Sima Toledano, Migdal Haemek (IL); Yakov Roizin, Afula (IL); Dov Vayer, Migdal Haemek (IL); Evgeny Pikhay, Haifa (IL); Roy Strul, Migdal Haemek (IL)

(73) Assignee: Tower Semiconductor Ltd., Migdal Haemek (IL)

(21) Appl. No.: 19/041,940

(22) Filed: Jan. 30, 2025

(51) Int. Cl. H10D 8/01; H10D 8/00; H10D 89/00

(52) U.S. Cl. CPC H10D 8/045; H10D 8/422; H10P 58/00

(57) ABSTRACT

There is provided a method of fabrication of the high voltage diode, the method includes (i) forming a temporary first contact mask above a highly doped region of a first doping type, the highly doped region is located above a portion of a P-N junction that is formed by a pair of layers of different doping types that are located above a highly doped substrate of a second doping type; (ii) forming a trench at an edge region, after a completion of the forming of the temporary first contact mask, the trench passes through the pair of layers and penetrates the highly doped substrate; (iii) forming a passivation layer on at least the trench; (iv) removing the temporary first contact mask to provide a first contact space; (v) forming the first contact at the first contact space by performing metal deposition that uses a shadow mask to deposit metal at the first contact space to provide an intermediate semiconductor item; and (vi) dicing the intermediate semiconductor item at the trench to provide the high voltage diode.

### BACKGROUND OF THE INVENTION

High voltage diodes operate at voltages that exceed 1000 volts.

The manufacturing of high voltage diodes includes generating a wafer that includes multiple dies-each die being associated with a single high voltage diode, and each high voltage die includes a first contact and a second contact that are used for electrical contact with an anode and a cathode of each high voltage diode, respectively.

There is a growing need to provide an accurate and cost effective method for fabricating high voltage diodes.

### SUMMARY

There is provided a method for manufacturing a high voltage diode, and a high voltage diode as illustrated in the application.

### BRIEF DESCRIPTION OF THE DRAWINGS

The subject matter being regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIGS. 1 and 2 illustrate example of methods;

FIGS. 3-7 illustrates examples of intermediate silicon items formed during various steps of the methods of FIGS. 1 and 2; and

FIG. 8 illustrates an example of a high voltage diodes wafer and of a shadow mask.

### DESCRIPTION OF THE PREFERRED EMBODIMENTS

There is provided a high voltage diode and a method for fabricating a high-voltage diode.

The suggested method is less costly and easier to implement in relation to manufacturing processes that passivate a high voltage diode die following the separation of the high voltage diode from other high voltage diode dies at the semiconductor wafer. The high voltage diodes typically employ p-n junctions with the junction depth of the order of tens-hundreds of micrometers, Deep isolated p-n junction are difficult to form using the tools available in CMOS foundries. The solution is to use the wafers, where the deep p-n junctions were fabricated at the whole surface of the wafer. In this case, there is a need for isolation of the edges of the formed individual diodes. The method of forming diode edge termination is taught in the current invention.

The suggested method also overcomes the difficulties of performing a lithographic process to define a space for a diode contact after the formation of a trench—as the method includes preliminary steps that prevent the leakage of photoresist materials deposition (required to define a space for the first contact) in the presence of a trench.

According to an embodiment, there is provided a method of fabrication of the high voltage diode.

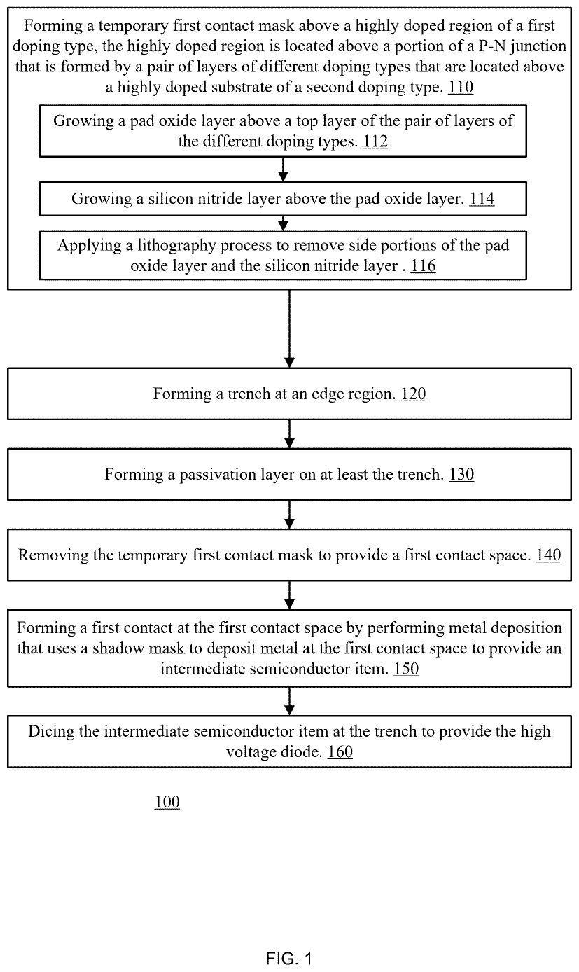

FIG. 1 illustrates method 100 of fabrication of a high voltage diode.

According to an embodiment, method 100 includes step 110 of forming a temporary first contact mask above a highly doped region of a first doping type, the highly doped region is located above a portion of a P-N junction that is formed by a pair of layers of different doping types that are located above a highly doped substrate of a second doping type.

The first doping type and the second doping type are selected from positive type doping (P-type) (P) and negative doping (N-type) (N).

In one example, the first doping type P-type, and the second doping type is N-type.

In another example, the first doping type is N-type and the second doping type is P-type.

Highly doping (for example N+doping or P+doping) may refer to doping that well exceeds (for example of by a factor of one thousand) “regular” doping. For example-highly doping may include adding a dopant atom per ten thousand intrinsic atoms while “regular doping may include adding a dopant atom per one hundred million intrinsic atoms. Other ratios of doping may define high and/or “normal” doping.

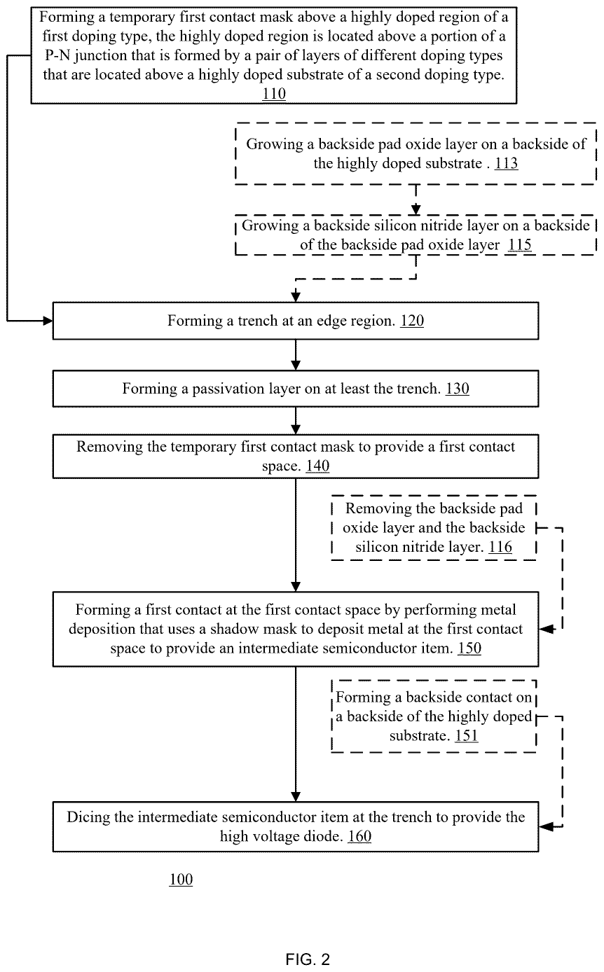

According to an embodiment, step 110 includes (see FIG. 2):
a. Step 112 of growing a pad oxide layer above a top layer of the pair of layers of the different doping types.
b. Step 114 of growing a silicon nitride layer above the pad oxide layer.
c. Step 116 of applying a lithography process to remove side portions of the pad oxide layer and the silicon nitride layer.

According to an embodiment, a thickness of the pad oxide layer ranges between two one hundred and three hundred Angstroms, and wherein a thickness of the silicon nitride layer ranges between 1500 and 2000 Angstrom.

According to an embodiment, method 100 also includes (see FIG. 1): step 113 of growing a backside pad oxide layer on a backside of the highly doped substrate (for example in parallel to step 112), step 115 of growing a backside silicon nitride layer on a backside of the backside pad oxide layer substrate (for example in parallel to step 112); and following step 130-step 117 of removing the backside pad oxide layer and the backside silicon nitride layer.

According to an embodiment the P-N junction is spaced apart from the upper surface of the pair of layers by 10 to 100 microns.

According to an embodiment, step 110 is followed by step 120 of forming a trench at an edge region, after a completion of the forming of the temporary first contact mask. The trench passes through the pair of layers and penetrates the highly doped substrate.

According to an embodiment the trench depth ranges between 150 and 150-250 microns.

According to an embodiment, the temporary first contact mask included a portion of a pad oxide layer and a portion of a silicon nitride layer.

According to an embodiment, step 120 is followed by step 130 of forming a passivation layer on at least the trench.

According to an embodiment, step 130 includes applying thermal wet oxidation.

According to an embodiment, step 120 includes reactive-ion etching/deep reactive-ion etching-as the depth of the trench may exceed 10 microns.

According to an embodiment, step 130 is followed by step 140 of removing the temporary first contact mask to provide a first contact space.

According to an embodiment, method 100 also includes (see FIG. 2): step 116 of removing the pad oxide layer and silicon nitride layer from a backside of the highly doped substrate (for example in parallel to step 140)

According to the embodiment, steps 140 and 141 includes selective removal of silicon nitride (SiN) and pad oxide. Processes for SiN and pad oxide removal do not require masking steps.

According to an embodiment, step 140 is followed by step 150 of forming a first contact at the first contact space by performing metal deposition that uses a shadow mask to deposit metal at the first contact space to provide an intermediate semiconductor item.

According to an embodiment, the first contact is a layered structure that comprises different layers of different materials.

According to an embodiment, wherein the different materials comprise silver, nickel, and titanium.

According to an embodiment, a thickness of a titanium layer ranges between 900 and 1300 Angstrom, a thickness of a nickel layer ranges between 3500 and 4500 Angstrom, and a thickness of a sliver layer ranges between 9000 and 11,000 Angstrom.

According to an embodiment, the shadow mask is a silicon wafer that comprises a silicon substrate that comprises apertures that correspond to first contact spaces of high-voltage diodes of different dies.

According to an embodiment, method 100 also includes (see FIG. 2) step 151 of forming a backside contact on a backside of the highly doped substrate following the step 140 of removing the temporary first contact mask. According to an embodiment, step 151 follows step 150 and involves a blanket (non-selective) deposition. According to an embodiment, step 151 is followed by step 150.

According to an embodiment, each one of the first contact and the backside contact is a layered structure that comprises different layers of different materials.

According to an embodiment, step 150 is followed by step 160 of dicing the intermediate semiconductor item at the trench to provide the high voltage diode.

According to an embodiment, the trench is maintained at least partially empty following the forming of the trench. This simplifies method and reduced costs as there is no need to fully fill the trench with temporary material and then remove the temporary material.

According to an embodiment, step 110 includes:
a. Receiving an item that includes a highly doped N+ substrate with a pair of layers of different doping types such as epitaxial layers (P-epitaxial layer and N-epitaxial layer) that create the P-N junction that is spaced apart from the upper surface of the item (for example spaced apart by 10-100 microns.
b. Forming the P+ region of the diode by implantation.
c. Defining the temporary first contact mask by (i) growing a pad oxidation layers (for example of thickness of 100-300 Angstrom) and a Silicon Nitride layers (for example of a thickness of 1500-2000 A) on the front side and backside of the item.

According to an embodiment, step 120 includes creating a trench (for example having a depth that ranges between 150 and 250 microns and a width that ranges between 200-800 microns) using photolithography and deep RIE silicon etch.

According to an embodiment, step 130 includes passivating all the item's surface, horizontal and vertical, including trench walls and trench bottom, excluding the temporary first contact mask with SiN and pad oxide underneth and the backside with the same SiN and pad oxide layers (for example, passivation having a thickness that ranges between 0.1 and 1 micron)

According to an embodiment, step 140 includes removing the SiN blocking area and the pad oxide of the termporary mask from the front side and the back side of the wafer using wet SiN and oxide etch.

According to an embodiment, step 150 includes depositiing of a front metal stack that contains a titanium layer, a nickel layer and a silver layer (for example of thickeness that ranges between 900-1300 Angstrom, 3500-4500 Angstrom and 9,000-11,000 Angetrom, respectively) using a metal evaporation or sputtering process through a shadow mask. According to an embodiment, the shadow mask is formed using a silicon wafer of the same size as the device wafer. The ame metal evaporation process is done without the shadow mask on the backside of the wafer to form blanket contact at the backside.

According to an embodiment, step 160 includes dicing the high voltage diodes dies in the regions of the trenchs.

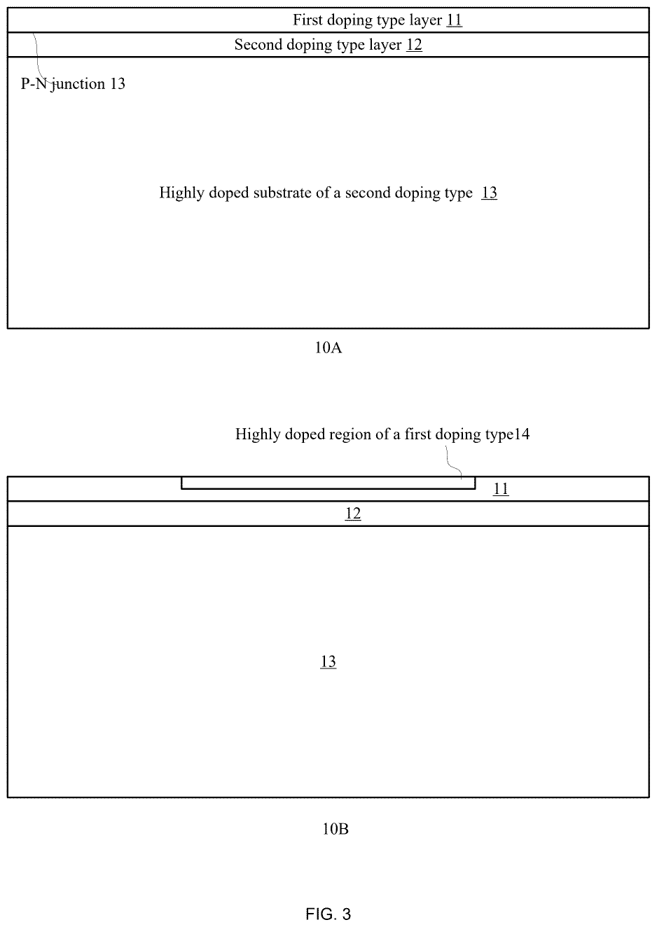

FIG. 3-7 illustrates the progress of various steps of method 100.

FIG. 3 illustrates an example of a first semiconductor item 10A that includes a P-N junction 13 that is formed by a pair of layers of different doping types that includes first doping type layer 11 and second doping type layer 12. The pair of layers are formed over a highly doped substrate of a second doping type 13.

FIG. 3 also illustrates an example of a second semiconductor item 10B that further includes highly doped region of a first doping type 14.

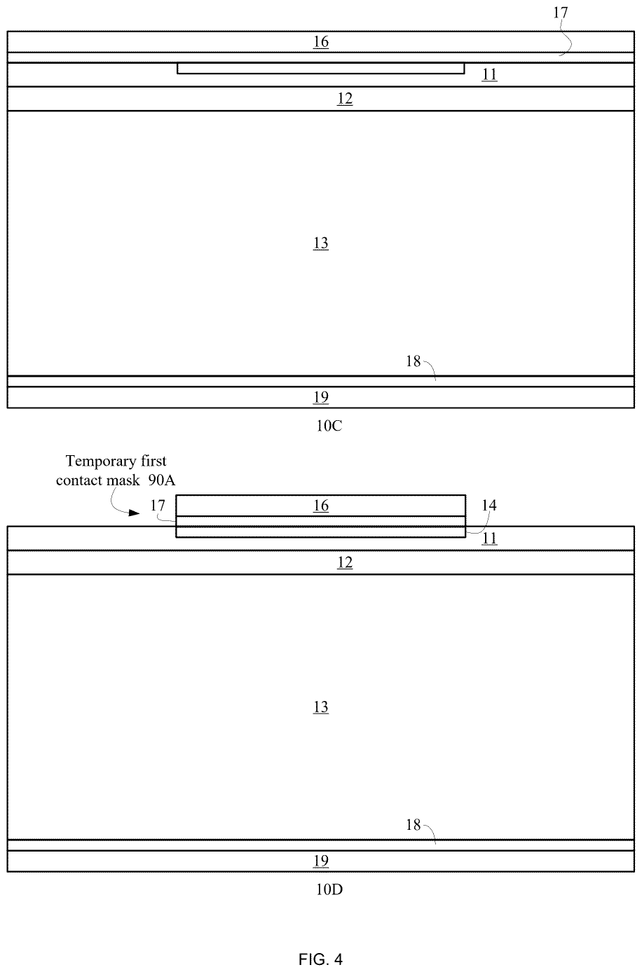

FIG. 4 illustrates an example of a third semiconductor item 10C that further includes pad oxide layer 17 and silicon nitride layer 16 formed on the first doping type layer 11. And pad oxide layer 18 and silicon nitride layer 19 formed on the backside of the highly doped substrate.

FIG. 4 also illustrates an example of a fourth semiconductor item 10D that includes temporary first contact mask 90A—following the removal of side portions of the pad oxide layer and the silicon nitride layer.

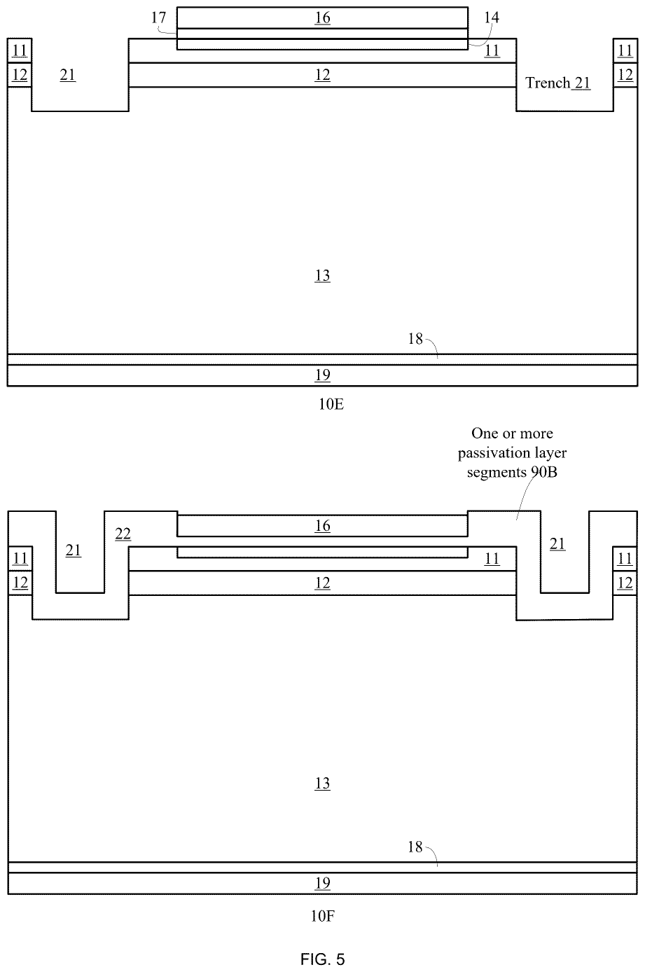

FIG. 5 illustrates an example of a fifth semiconductor item 10E following the formation of trench 21.

FIG. 5 also illustrates an example of a sixth semiconductor item 10F that also includes one or more passivation layer segments 90B.

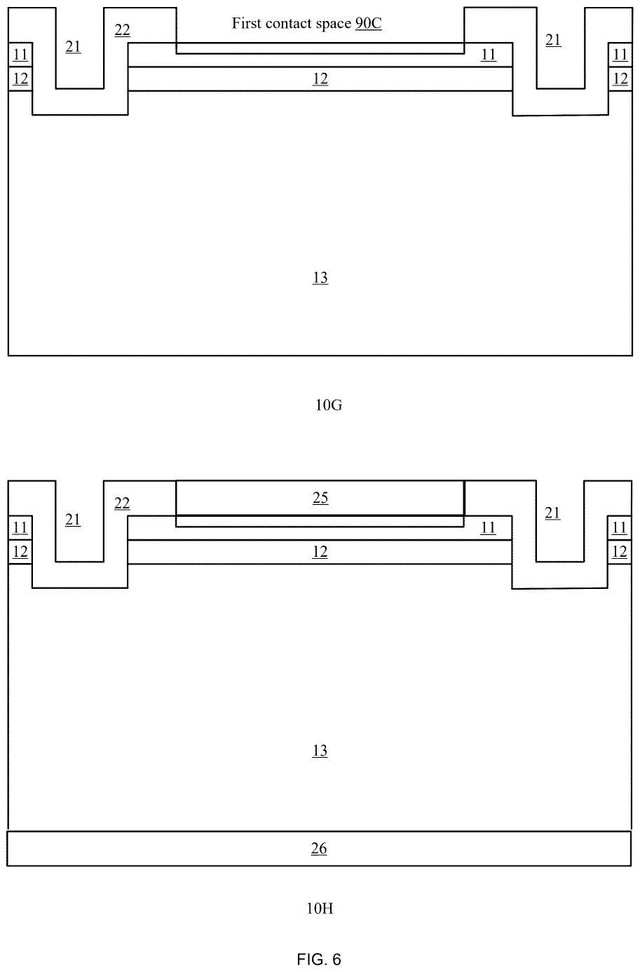

FIG. 6 illustrates an example of a seventh semiconductor item 10G following the formation of first contact space 90C—by removing the temporary first contact mask 90A. and removing the silicon nitride layer 19 and pad oxide layer 18 from the backside of the wafer.

FIG. 6 also illustrates an example of an eighth semiconductor item 10H (also referred to as an intermediate semiconductor item) after first contact 25 was formed in the first contact space 90C and after second contact 26 was formed as blanket contact on the highly dopped substrate backside.

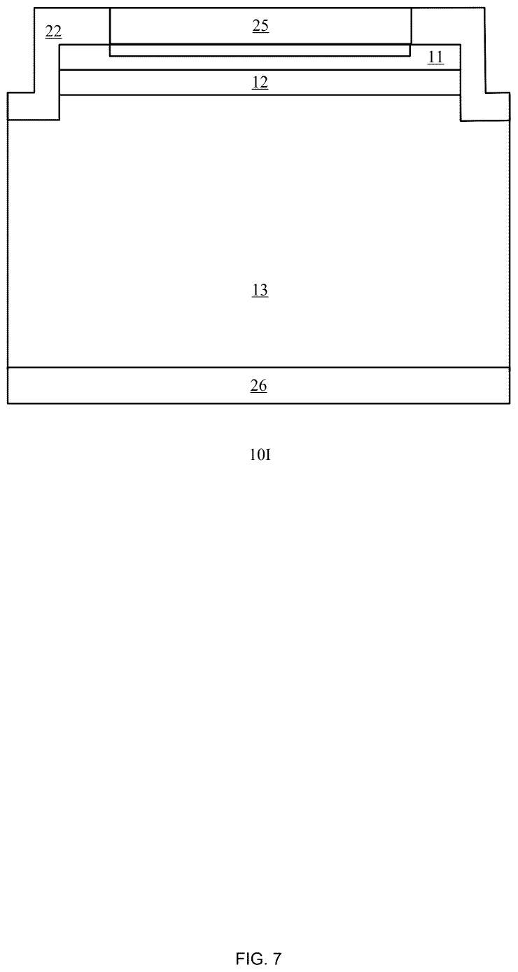

FIG. 7 illustrates an example of a high voltage diode 10I following the dicing of the eight intermediate semiconductor item 10H.

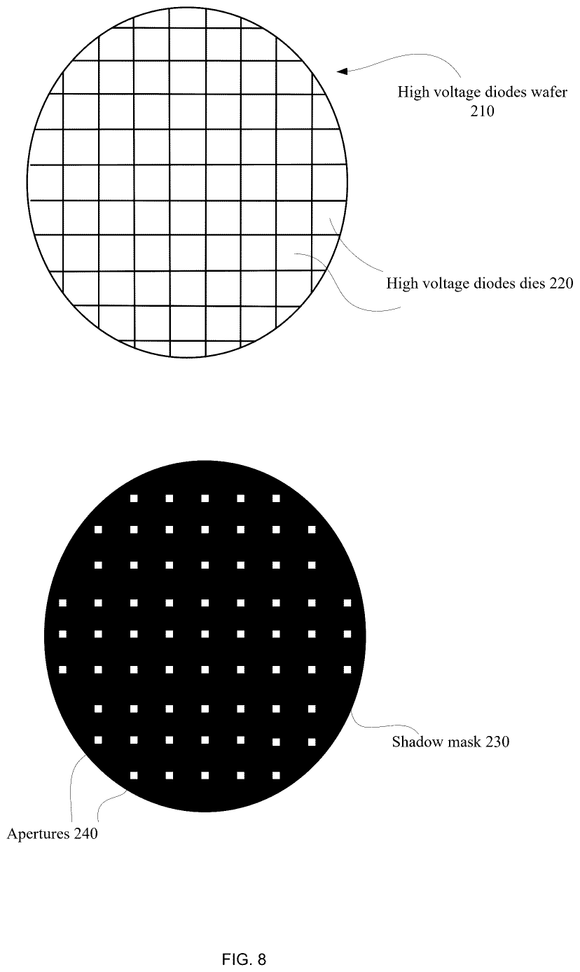

FIG. 8 illustrates a high voltage diodes wafer 210 that includes multiple high voltage diode dies 220, and shadow mask 230 that includes apertures 240 corresponding to the first contacts of the high voltage diodes 220.

It will be appreciated that for simplicity and clarity of illustration, elements shown in the figures have not necessarily been drawn to scale. For example, the dimensions of some of the elements may be exaggerated relative to other elements for clarity. Further, where considered appropriate, reference numerals may be repeated among the figures to indicate corresponding or analogous elements.

In the foregoing detailed description, numerous specific details are set forth to provide a thorough understanding of the invention. However, it will be understood by those skilled in the art that the present invention may be practiced without these specific details. In other instances, well-known methods, procedures, and components have not been described in detail so as not to obscure the present invention.

The subject matter being regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings.

Because the illustrated embodiments of the present invention may for the most part, be implemented using electronic components and circuits known to those skilled in the art, details will not be explained in any greater extent than that considered necessary as illustrated above, for the understanding and appreciation of the underlying concepts of the present invention and in order not to obfuscate or distract from the teachings of the present invention.

The term “and/or” means additionally or alternatively. For example-A and/or B may mean only A, only B, or both A and B.

Any reference to any of the terms “comprise”, “comprises”, “comprising” “including”, “may include” and “includes” may be applied, mutatis mutandis, to any of the terms “consists”, “consisting”, “consisting essentially of”.

In the foregoing specification, the invention has been described with reference to specific examples of embodiments of the invention. It will, however, be evident that various modifications and changes may be made therein without departing from the broader spirit and scope of the invention as set forth in the appended claims.

Moreover, the terms “front,” “back,” “top,” “bottom,” “over,” “under” and the like in the description and in the claims, if any, are used for descriptive purposes and not necessarily for describing permanent relative positions. It is understood that the terms so used are interchangeable under appropriate circumstances such that the embodiments of the invention described herein are, for example, capable of operation in other orientations than those illustrated or otherwise described herein.

Furthermore, those skilled in the art will recognize that boundaries between the above described operations merely illustrative. The multiple operations may be combined into a single operation, a single operation may be distributed in additional operations and operations may be executed at least partially overlapping in time. Moreover, alternative embodiments may include multiple instances of a particular operation, and the order of operations may be altered in various other embodiments.

However, other modifications, variations and alternatives are also possible. The specifications and drawings are, accordingly, to be regarded in an illustrative rather than in a restrictive sense.

In the claims, any reference signs placed between parentheses shall not be construed as limiting the claim. The word ‘comprising’ does not exclude the presence of other elements or steps than those listed in a claim. Furthermore, the terms “a” or “an,” as used herein, are defined as one or more than one. Also, the use of introductory phrases such as “at least one” and “one or more” in the claims should not be construed to imply that the introduction of another claim element by the indefinite articles “a” or “an” limits any particular claim containing such introduced claim element to inventions containing only one such element, even when the same claim includes the introductory phrases “one or more” or “at least one” and indefinite articles such as “a” or “an.” The same holds true for the use of definite articles. Unless stated otherwise, terms such as “first” and “second” are used to arbitrarily distinguish between the elements such terms describe. Thus, these terms are not necessarily intended to indicate temporal or other prioritization of such elements.

While certain features of the invention have been illustrated and described herein, many modifications, substitutions, changes, and equivalents will now occur to those of ordinary skill in the art. It is, therefore, to be understood that the appended claims are intended to cover all such modifications and changes as fall within the true spirit of the invention.

We claim:

1. A method of fabrication of the high voltage diode, the method comprising:
forming a temporary first contact mask above a highly doped region of a first doping type, the highly doped region is located above a portion of a P-N junction that is formed by a pair of layers of different doping types that are located above a highly doped substrate of a second doping type;
forming a trench at an edge region, after a completion of the forming of the temporary first contact mask, the trench passes through the pair of layers and penetrates the highly doped substrate;
forming a passivation layer on at least the trench;
removing the temporary first contact mask to provide a first contact space;
forming the first contact at the first contact space by performing metal deposition that uses a shadow mask to deposit metal at the first contact space (to provide an intermediate semiconductor item; and
dicing the intermediate semiconductor item at the trench to provide the high voltage diode.

2. The method according to claim 1, comprising maintaining the trench at least partially empty following the removing the temporary first contact mask.

3. The method according to claim 1, wherein the forming of the trench comprises reactive-ion etching.

4. The method according to claim 1, wherein the forming of the first contact mask comprises:
a. growing a pad oxide layer above a top layer of the pair of layers of the different doping types;
b. growing a silicon nitride layer above the pad oxide layer; and
c. applying a lithography process to remove side portions of the pad oxide layer and the silicon nitride layer.

5. The method according to claim 4, wherein a thickness of the pad oxide layer ranges between one hundred and three hundred Angstrom, and wherein a thickness of the silicon nitride layer ranges between 1500 and 2000 Angstrom.

6. The method according to claim 4, further comprising growing a backside pad oxide layer on a backside of the highly doped substrate, growing a backside silicon nitride layer on a backside of the backside pad oxide layer; and following the removing the temporary first contact mask.

7. The method according to claim 1 wherein the forming of the passivation oxide comprises applying thermal wet oxidation.

8. The method according to claim 1 wherein the temporary first contact mask comprises a portion of a pad oxide layer and a portion of a silicon nitride layer.

9. The method according to claim 1 wherein the first contact is a layered structure that comprises different layers of different materials.

10. The method according to claim 1 wherein the different materials comprise silver, nickel, and titanium.

11. The method according to claim 10 wherein a thickness of a titanium layer ranges between 900 and 1300 Angstrom, a thickness of a nickel layer ranges between 3500 and 4500 Angstrom, and a thickness of a sliver layer ranges between 9000 and 11,000 Angstrom.

12. The method according to claim 1, wherein the shadow mask is a silicon wafer that comprises apertures that correspond to first contact spaces of high-voltage diodes of different dies.

13. The method according to claim 1, comprising forming a backside contact on a backside of the highly doped substrate following removing the temporary first contact mask.

14. The method according to claim 13 wherein each one of the first contact and the backside contact is a layered structure that comprises different layers of different materials.

15. A high voltage diode, comprising:
a pair of layers of different doping types that form a P-N junction;
a highly doped region of a first doping type that is located above a portion of the P-N;
a highly doped substrate of a second doping type that is located below the pair of layers;
a trench;
one or more passivation layer segments that only partially fill the trench and also cover portions of the pair of layers;
a backside contact that is formed on a backside of the highly doped substrate.

16. The high voltage diode, according to claim 14 wherein the high voltage diode is manufactured without fully filling the trench.

17. The high voltage diode, according to claim 14 wherein the high voltage diode is manufactured by a method that comprises:
forming a temporary first contact mask above the highly doped region;
forming a trench at an edge region, after a completion of the forming of the temporary first contact mask, the trench passes through the pair of layers and penetrates the highly doped substrate;
forming a passivation layer on at least the trench;
removing the temporary first contact mask to provide a first contact space;
forming the first contact at the first contact space by performing metal deposition that uses a shadow mask to deposit metal at the first contact space to provide an intermediate semiconductor item; and
dicing the intermediate semiconductor item at the trench to provide the high voltage diode.
